(19) United States
(12) Patent Application Publication
(10) Pub. No.: US 2005/0078538 A1
(43) Pub. Date: Apr. 14, 2005

(54) Selective address-range refresh

(76) Inventor: Rainer Hoehler, Neubiberg (DE)

Correspondence Address: BRINKS HOFER GILSON & LIONE;INFINEON, PO BOX 10395, CHICAGO, IL, 60610, US

(21) Appl. No.: 10/675,594

(22) Filed: Sep. 30, 2003

(51) Int. Cl. G11C 7/00

(52) U.S. Cl. 365/222

(57) ABSTRACT

A method of refreshing memory banks of a memory device that receives command signals from a memory controller. The method including monitoring command signals received by the memory device and refreshing several memory banks of the memory device based on the monitored command signals so as to avoid unnecessary power consumption for refreshing the several memory banks.

### BACKGROUND OF THE INVENTION

1. Field of the Invention

The present invention relates to the field of memory systems, and in particular memory systems that employ a refresh operation.

2. Discussion of Related Art

It is well known in the art that various types of personal computers, such as desktop computers and battery-operated notebook computers, include a central processing unit (CPU) and a main memory to which the central processing unit accesses. The central processing unit executes programs loaded on the main memory, and sequentially writes the results obtained by program execution into work areas in banks of the main memory so that the computer processing is performed.

The main memory is composed of a random access memory (RAM), such as SRAM (static RAM) and DRAM (dynamic RAM). For the main memory, DRAM is generally used because DRAM has a simple cell structure and is cheaper. Accordingly, the discussion to follow will concentrate on known DRAM memory systems.

DRAM memory cells in the main memory are arranged as a matrix. In order to address memory cells individually, first, an Activate Command is issued with a row address, and then, read or write commands are issued with the column address. In the DRAM memory cells, data are stored as electric charges on a capacitor. Thus, when data are written to the memory cells and are left for an extended period of time, the charges leak from the capacitor and the stored data are lost. To prevent such data loss, the written data needs to be refreshed/rewritten at predetermined time intervals.

Known refresh operations include accessing a specific memory cell row to refresh all of the cells along that row. In order to refresh all of the row addresses, a refresh address counter is required that designates refresh addresses sequentially. In addition, the known refresh operations provide either a refresh cycle or issues a refresh request at a predetermined period of time.

One known method to refresh the memory contents is to serially access all rows with an activate—precharge command-sequence. For this method, a refresh address counter designates refresh row addresses that must be provided from outside the memory.

A second known refresh operation is generally known as autorefresh where a refresh request is supplied to the memory by sending an Autorefresh command. The refresh addresses are generated by an address counter within the DRAM such that no external address counter is required.

A third known refresh operation is self-refresh, which allows the data in the DRAM to be refreshed even while the rest of the system is powered down. During self-refresh an internal timing circuit and an internal address counter generate the refresh operations for all rows in time intervals sufficiently short to keep the stored data intact. This allows for very low power consumption since the time-intervals between refreshes can be optimized and all other circuits can be powered down.

FIG. 1 is a schematic diagram illustrating the arrangement of a known computer system 100 that has both the normal refresh function and the self-refresh function. A DRAM device 102, including a DRAM array 103, and a memory controller unit 104 are connected to each other by a bus 106 and an I/O device 108. Outside the DRAM device 102 are provided a normal refresh circuit 110, which forms a part of the memory controller unit 104 that performs a refresh operation while the memory controller unit 104 is accessing the memory, and a global clock 112. Inside the DRAM device 102 are provided a self-refresh circuit 114 that performs a relatively slow refresh operation, and an internal timing generator 116 that supplies a relatively long interval signal to the self-refresh circuit 114. In addition, a switch 118 is provided to select either the normal refresh circuit 110 or the self-refresh circuit 114 for refreshing the DRAM device 102.

One disadvantage of such a system is that all address rows of the DRAM 103 are self-refreshed even if some address rows do not contain data. Accordingly, there is a waste in power used during self-refreshing.

### SUMMARY OF THE INVENTION

One aspect of the present invention regards a memory control system that includes a memory controller and a memory device connected to the memory controller via a command bus, wherein command signals are directed from the memory controller to the memory device. The memory device includes one or more memory banks, a row address register and a command decoder that is connected to the row address register and receives the command signals and controls the contents of the row address register. A refresh circuit is connected to the one or more memory banks and the row address register, wherein the refresh circuit avoids unnecessary power consumption for refreshing the one or more memory banks.

A second aspect of the present invention regards a memory control system including a memory controller, a memory device connected to the memory controller via a command bus, wherein command signals are directed from the memory controller to the memory device. The memory device includes one or more memory banks, a first row address register, a second row address register and a command decoder that is connected to the first row address register and the second row address register and receives the command signals and controls the contents of the first row address register and the second row address register. A refresh circuit connected to the one or more memory banks and the row address register, wherein the refresh circuit avoids unnecessary power consumption for refreshing the one or more memory banks.

A third aspect of the present invention regards a memory control system including a memory controller, a memory device connected to the memory controller via a command bus, wherein command signals are directed from the memory controller to the memory device. The memory device includes one or more memory banks, one row address register for each of the one or more memory banks and a command decoder that is connected to each of the row address registers and receives the command signals and controls the contents of the row address registers. A refresh circuit connected to the one or more memory banks and the row address registers, wherein the refresh circuit avoids unnecessary power consumption for refreshing the one or more memory banks.

A fourth aspect of the present invention regards a method of refreshing one or more memory banks of a memory device that receives command signals from a memory controller. The method including monitoring command signals received by a memory device and refreshing the one or more memory banks based on the monitored command signals so as to avoid unnecessary power consumption for refreshing the one or more memory banks.

Each of the above aspects of the present invention provides the advantage of reducing power.

The present invention, together with attendant objects and advantages, will be best understood with reference to the detailed description below in connection with the attached drawings.

### BRIEF DESCRIPTION OF THE DRAWINGS

FIG. 1 schematically shows an embodiment of a known memory device that includes normal and self-refresh circuits;

FIG. 2 schematically shows a first embodiment of a memory system in accordance with the present invention;

FIG. 3 shows a flow chart of a first embodiment of a refresh process in accordance with the present invention to be used with the memory system of FIG. 2;

FIG. 4 schematically shows a second embodiment of a memory system in accordance with the present invention;

FIG. 5 shows a flow chart of a second embodiment of a refresh process in accordance with the present invention to be used with the memory system of FIG. 4;

FIG. 6 schematically shows a third embodiment of a memory system in accordance with the present invention;

FIG. 7 shows a flow chart of a third embodiment of a refresh process in accordance with the present invention to be used with the memory system of FIG. 6;

FIG. 8 schematically shows a fourth embodiment of a memory system in accordance with the present invention;

FIG. 9 shows a flow chart of a fourth embodiment of a refresh process in accordance with the present invention to be used with the memory system of FIG. 8;

FIG. 10 schematically shows a fifth embodiment of a memory system in accordance with the present invention;

FIG. 11 shows a flow chart of a fifth embodiment of a refresh process in accordance with the present invention to be used with the memory system of FIG. 10;

FIG. 12 schematically shows a sixth embodiment of a memory system in accordance with the present invention; and

FIG. 13 shows a flow chart of a sixth embodiment of a refresh process in accordance with the present invention to be used with the memory system of FIG. 4;

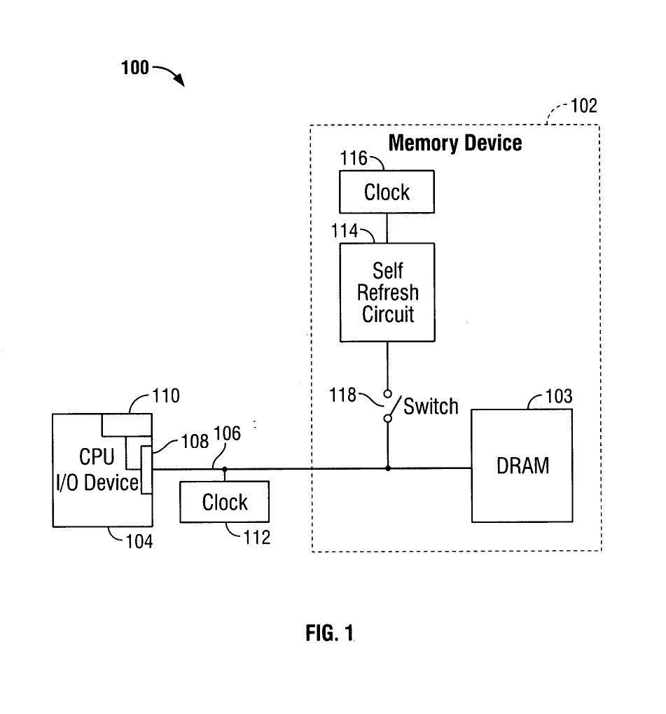

### DETAILED DESCRIPTION OF THE INVENTION

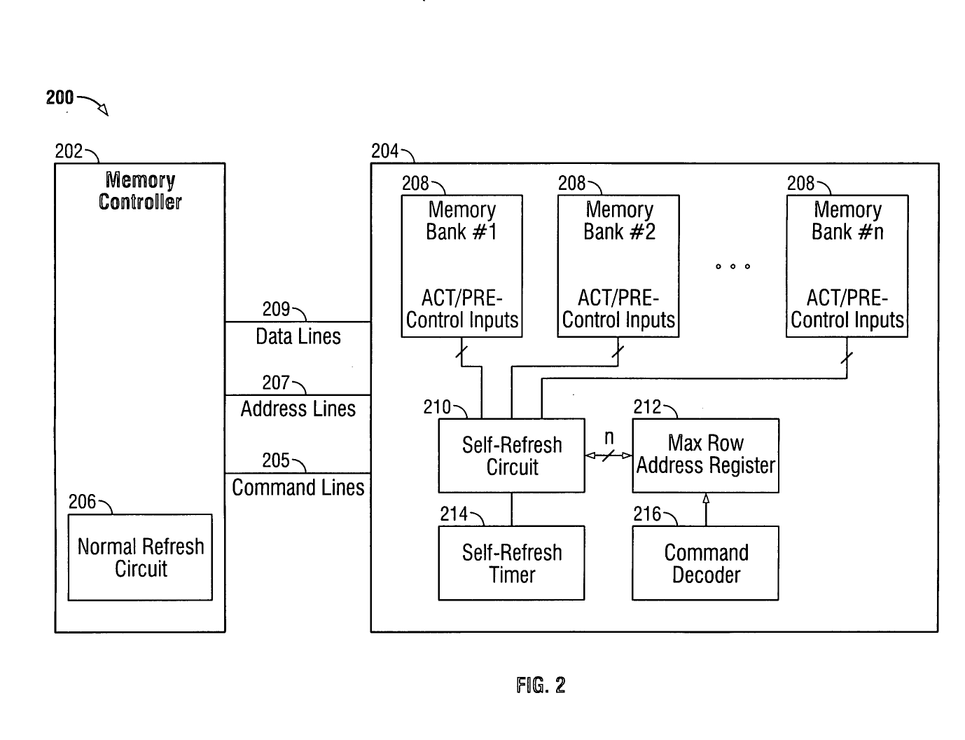

The present invention is best understood by a review of the embodiments and modes of operation represented by FIGS. 2-13. As shown in FIG. 2, a memory system 200 includes a memory controller 202 and a memory device 204. The memory controller 202 executes memory accesses (including both read accesses and write accesses) of the memory device 204 in response to memory access requests issued by a central processing unit (not illustrated).

The memory controller 202 and the memory device 204 are connected together by a command bus 205 of command signals, an address bus 207 of address signals, and a data bus 209 of data signals, clock signals (not illustrated) and datastrobe signals (not illustrated).

The memory controller 202 has a normal refresh circuit 206 that performs a normal refresh operation in a manner similar to that described previously. The normal refresh circuit 206 provides a normal refresh cycle every predetermined interval, by sending an autorefresh signal to the memory device 204 through the command bus 205. Incorporated in the memory device 204 is a self-refresh circuit 210, a self-refresh timer 214, a command decoder 216, and a maximum row address register 212. The self-refresh circuit 210 includes a refresh address counter for incrementing a row address to be refreshed at each refresh cycle, and a controller for, in response to a refresh request, controlling access to a row address such that all rows get refreshed within a given time period to avoid loss of memory contents. The address counter covers all row-addresses and restarts at the lowest row address after the highest row-address has been refreshed. The incorporated refresh circuit 210 executes either a “normal refresh” operation and a “self-refresh” operation upon receipt of a corresponding refresh request. A normal refresh operation is realized by responding to a memory autorefresh refresh request from the normal refresh circuit 206, and by accessing a designated row address.

A self-refresh operation is begun when the memory device 204 is put into self-refresh mode through the respective command sequence from the memory controller 200. In the self-refresh mode, a self-refresh request is issued to the self-refresh circuit 210 from the memory controller 200 every predetermined time period that is triggered by a self-refresh timer 214. In state-of-the art memories devices, such a self-refresh circuit leads to an activate/precharge sequence for all memory banks 208 of the memory device 204 in parallel. An example of a known self-refresh circuit that can be adapted for use with the present invention is the 256 Mbit-DDR-SDRAM manufactured and sold by Infineon under the part number HYB25D25616OBT-6.

As shown in FIG. 2, the memory device 204 includes a maximum row address register 212 that is in communication with both a command decoder 216 and the self-refresh circuit 210. It is a register which stores a single number ranging from the lowest (usually 0) to the highest row-address of the memory banks 208.

The command decoder monitors all write commands directed to the memory banks 208 and controls the contents of the maximum row address register 212. In the discussion to follow, the contents of the maximum row address register 212 will be denoted as ROWₘₐₓ, a digital value which can cover the same range as the row-address space of the memory device 204.

The digital value of ROWₘₐₓ of the maximum row address register 212 is initially set to zero during the power-up sequence of the memory device 204. Afterwards, the value of ROWₘₐₓ of the maximum row address register 212 is controlled by the command decoder 216 of the memory device 204. Whenever a write-command is issued to the memory device 204, the command decoder 216 decodes this write command and also decodes the row-address to which data are written. Whenever the decoded row-address is higher than the value of ROWₘₐₓ presently stored in the maximum row address register 212, then the value of ROWₘₐₓ is updated to have a value that corresponds to the presently decoded row-address.

In the case when memory contents are not relevant for the system anymore and thus no refreshing is required anymore, a command sequence, usually defined as an extended mode register set can be used to program/reset the value of ROWₘₐₓ of the maximum row address register 212 to zero or with an alternative implementation to any programmed value.

The self-refresh circuit 210 monitors the contents of the maximum row address register 212 and starts the activate/precharge sequence only for those rows with an address lower or equal than the stored value of ROWₘₐₓ of the maximum row address register 212. For those rows with addresses that have a value that is greater than the stored value of ROWₘₐₓ, the self-refresh circuit 210 suppresses the refresh of wordlines of those rows. Thus, the circuit 210 avoids unnecessary power consumption for refreshing rows which are defined to not require to be refreshed by the maximum row address register 212. The circuit 210 can be altered in such a way that it either checks the maximum row address register 212 1) only in case of self-refresh mode or 2) both in self-refresh and auto-refresh mode.

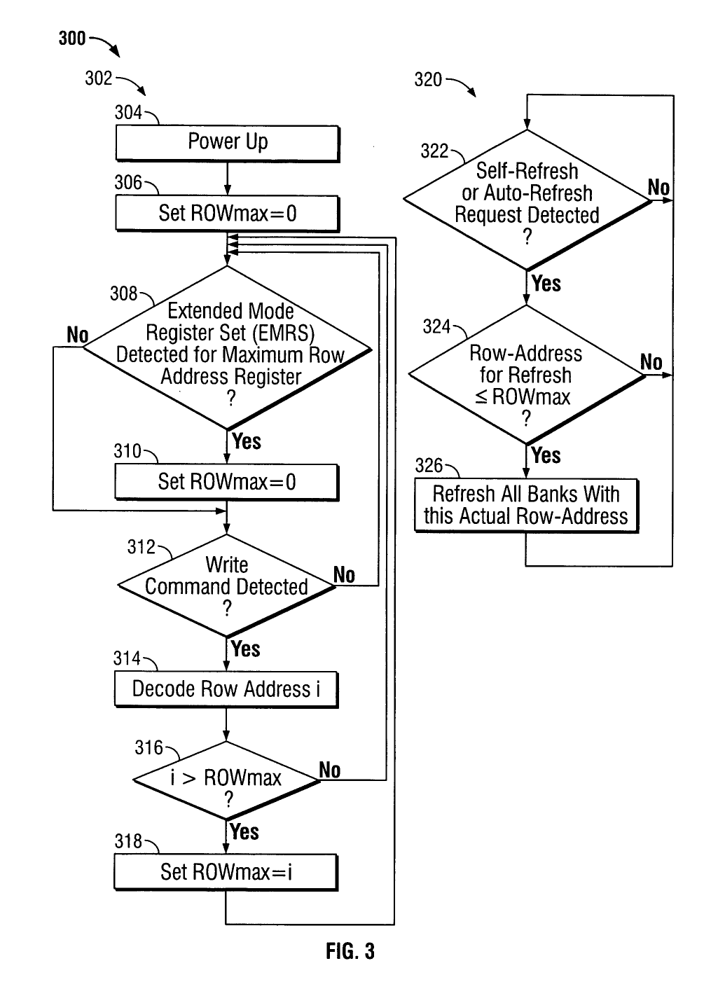

As shown in FIG. 3, two parallel processes performed by decoder 216 are controlling the self-refresh—and with respective implementation also autorefresh—process 300. The two processes are performed by a global control circuit that includes the command decoder 216. The sub-process 302 controls the contents of the maximum row address register 212.

As shown in FIG. 3, the self-refresh process 300 involves at power up (step 304) resetting the value ROWₘₐₓ stored in the maximum-row address register 212 to zero per step 306. Next, the row-addresses of commands sent to the memory banks 208 are analyzed in the manner set forth below. In particular, detection of an extended mode register access for the maximum row address register 212 is performed per step 308. If extended mode register access is detected per step 308, then the value of ROWₘₐₓ of the maximum row address register 212 is reset to the value 0 (step 310) or alternatively programmed to any other value (not illustrated) so as to declare the contents of the particular bank in question irrelevant. If an extended mode register access is not detected per step 308, then the value of ROWₘₐₓ is not altered.

Irrespective of whether or not an extended mode register access is detected per step 308, the presence of a write command is determined per step 312. If a write command is detected, then the row-address i gets decoded by command decoder 216 per step 314. If no write command is decoded then the process returns to step 308, as shown in FIG. 3, where another command sent to the memory banks 208 is monitored.

If a write command is detected, a comparison between the decoded value i and the value of ROWₘₐₓ is performed per step 316. In particular, if the decoded value i of the row-address is greater than the value ROWₘₐₓ, the value ROWₘₐₓ is set to the decoded value i and stored in the maximum row address register per step 318. Then the process is repeated starting at step 308 where another command sent to the memory banks 208 is monitored.

Note that if the decoded value i is less than or equal to the value ROWₘₐₓ, per step 316, then the above-described process is repeated at step 308 where another command sent to the memory banks 208 is monitored.

Note that that the addresses monitored at step 308 in the process described above are not done sequentially with respect to each memory bank 208. An alternative manner of determining the maximum row address is to determine the maximum row address for each memory block 208 separately and using the greatest value of the determined set of maximum row addresses as the value of ROWₘₐₓ.

The subprocess 320 shows the behavior during self-refresh and autorefresh requests. In particular, the command decoder 216 detects whenever a self-refresh or auto-refresh request for any row-address occurs per step 322. If no self-refresh or autorefresh is detected per step 322, then the process is then repeated and returns to step 322. If a self-refresh or autorefresh request is detected, then the value of the requested row-address for the refresh is compared with the value of ROWₘₐₓ per step 324.

If the value of the requested row-address is lower or equal to the value ROWₘₐₓ of the maximum row address register, then the rows of all banks 208 with this row-address get refreshed per step 326. The process is then repeated and returns to step 322.

Note that should the value of the requested row-address be determined in step 324 to be higher than the value ROWₘₐₓ, then the refresh request gets ignored and the process returns to step 322, which results in lower power consumption for the refresh.

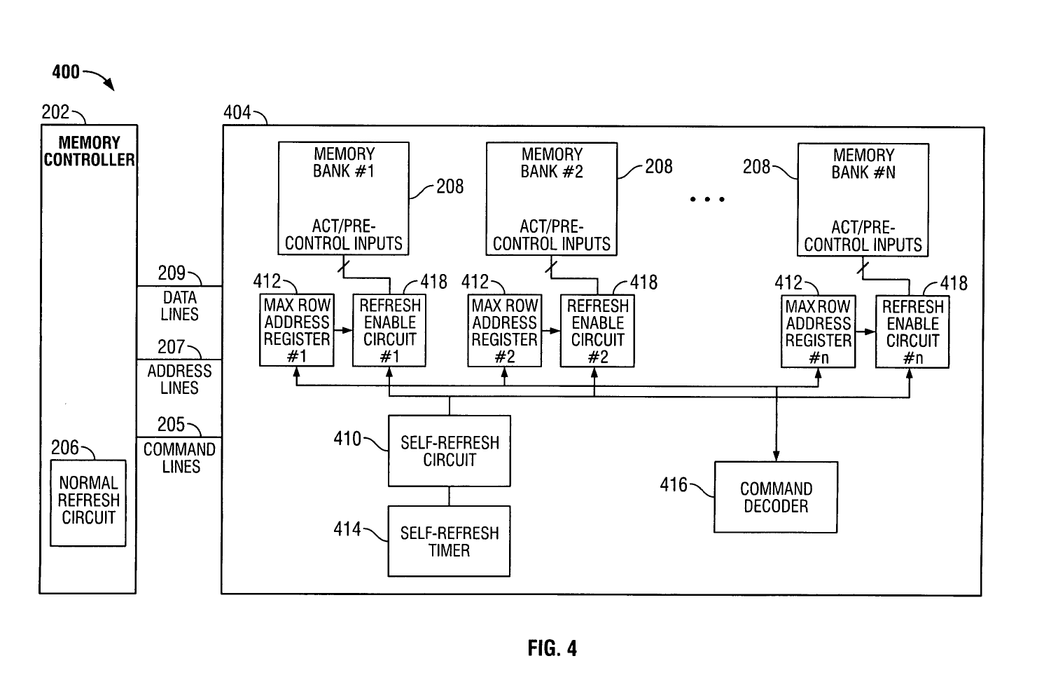

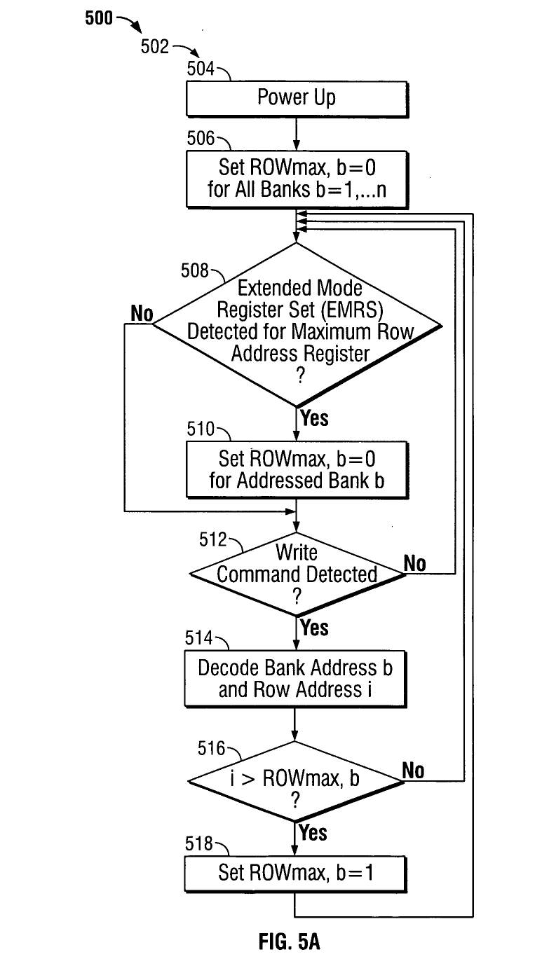

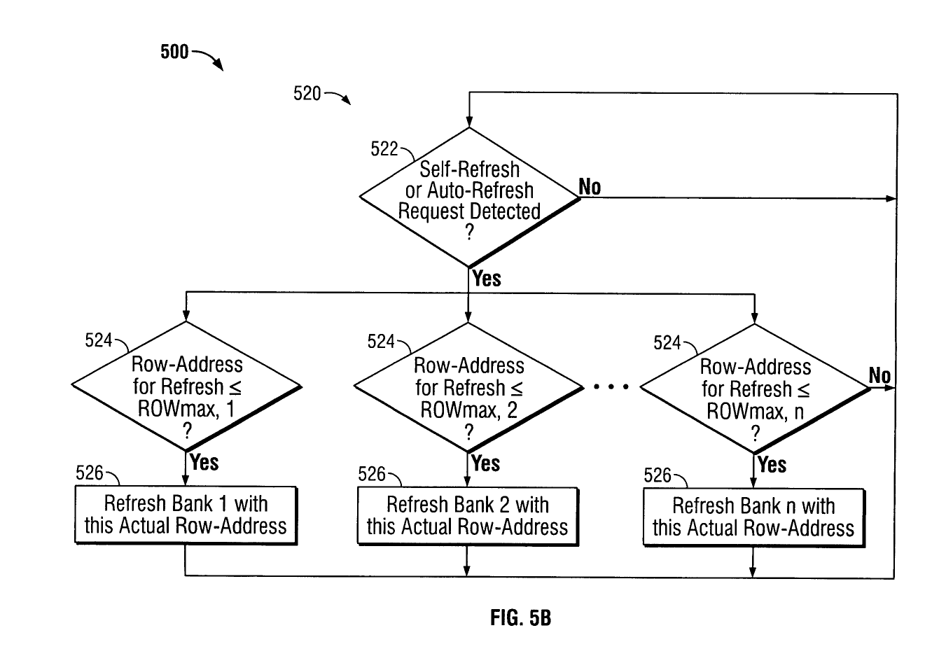

An alternative embodiment of a self-refresh memory device and corresponding self-refresh process are shown in FIGS. 4-5, wherein components and processes similar to those shown in FIGS. 2-3 are identified with like numerals. In particular, a memory system 400 includes a memory controller 202 and a memory device 404. The memory controller 202 has a normal refresh circuit 206 that performs a normal refresh operation in a manner similar to that described previously as explained previously with respect to FIGS. 2-3.

The memory controller 202 and the memory device 404 are connected together by a bus 205 of command signals, a bus 207 of address signals, a bus 209 of data signals, clock signals (not illustrated) and datastrobe signals (not illustrated) in a manner similar to that described previously with respect to FIGS. 2-3.

The memory device 404 has memory banks 208. Different from the memory device 204 in FIG. 2, the memory device 404 in this kind of implementation includes one maximum row address register 412 per memory bank 208. It also includes refresh enable circuits 418, one for each memory bank 208.

The command decoder 416 monitors all write commands directed to the memory banks 208 and controls the contents of the maximum row address registers 412. In the discussion to follow, each bank address will be denoted as b with b=1, . . . n with n denoting the total number of memory banks 208. The contents of the maximum row address register, connected to bank b will be denoted as ROW_{max,b}, a digital value which can cover the same range as the row-address space of the memory device.

The contents ROW_{max, b} (b=1, 2, . . . n) of all maximum row address are set to zero at the power-up sequence of the memory device 404. Afterwards, the contents of the maximum row address registers 412 are controlled by the command decoder 416 of the memory device 404. Whenever a write-command is issued to the memory device 404, the command decoder 416 decodes this write command and also decodes the bank address b and the row-address to which data are written. The decoder 416 then compares the value ROW_{max, b} of the maximum row address register corresponding to the bank b and the row-address of the decoded write command. If the row-address of the decoded write command is greater than the value ROW_{max, b} of the maximum row address register 412 of the addressed bank b, the value ROW_{max, b} of the maximum row address register 412 for bank b is changed to value of the row-address of the decoded write command. A command sequence—usually defined as an extended mode register set—can be used to reset the maximum row address registers 412 of all banks 208 to zero. Alternatively, an implementation is possible where each maximum row address register is reset individually with an extended mode register. Another implementation can allow setting the contents of all maximum row address registers to a programmable value. Another implementation allows setting the contents of each maximum row address register to a programmable value individually.

The self-refresh circuit 410 shown in FIG. 4 sends refresh requests, including the row-address information, to refresh enable circuits 418 for all banks 208. These refresh enable circuits 418 monitor the contents of the maximum row address registers for a corresponding memory bank 208. Only if the row-address of the refresh request from the self-refresh circuit 410 is lower or equal to the value of ROW_{max,b} of the maximum row-address register 412 of a bank b, a refresh sequence is started for bank b. The circuit 410 can be altered in such a way that it either does check the maximum row address register only in case of self-refresh mode or both in self-refresh and auto-refresh mode.

As shown in FIG. 5, the self-refresh process 500 involves at power up (step 504) resetting the value ROW_{max, b} stored in the maximum-row address registers 412 for each memory bank b (b=1, 2, . . . n) to zero per step 506. Next, the row-addresses of commands sent to the memory banks 208 are analyzed in the manner set forth below. In particular, detection of an extended mode register access for each of the maximum row address registers 412 is performed per step 508. If extended mode register access for a particular bank b is detected per step 508, then the value of ROWₘₐₓ; b of the maximum row address register 412 for addressed bank b is reset to the value 0 (step 510) or alternatively programmed to any other value (not illustrated) so as to declare the contents of the particular bank in question irrelevant. If an extended mode register access is not detected per step 508, then the value of ROW_{max, b} is not altered.

Irrespective of whether or not an extended mode register access is detected per step 508, the presence of a write command is determined per step 512. If a write command is detected, then the row-address i and addressed bank b gets decoded by command decoder 416 per step 514. If no write command is decoded then the process returns to step 508, as shown in FIG. 5, where another command sent to the memory banks 208 is monitored.

If a write command is detected, the bank address b is decoded and a comparison between the decoded value i of the row-address and the value of ROW_{max, b} is performed per step 516. In particular, if the decoded value i of the row-address is greater than the value ROW_{max, b}, the value ROW_{max, b} is set to the decoded value i and stored in the maximum row address register 412 corresponding to bank b per step 518. Then the process is repeated starting at step 508 where another command sent to the memory banks 208 is monitored.

Note that if the decoded value i is less than or equal to the value ROW_{max, b}, per step 316, then the above-described process is repeated at step 508 where another command sent to the memory banks 208 is monitored.

The subprocess 520 shows the behavior during self-refresh and autorefresh requests. In particular, the command decoder 416 detects whenever a self-refresh or auto-refresh request for any row-address of a particular bank b occurs per step 522. If no self-refresh or autorefresh is detected per step 522, then the process is then repeated and returns to step 522. If a self-refresh or autorefresh request is detected, then several steps are started in parallel, one for each bank 208. In particular, the value of the requested row-address for the refresh is compared by the refresh enable circuits 418 in parallel with each of the values of ROWₘₐₓ b of the banks 1, 2, b per step 524.

If the value of the requested row-address is lower or equal to the value ROW_{max, b} of the maximum row address register 412 for bank b, then bank b gets refreshed at this row-address of the refresh request per step 526. The process is then repeated and returns to step 522.

Note that should the value of the requested row-address be determined in step 524 to be higher than the value ROW_{max, b}, then the refresh request for bank b of the requested row-address is ignored and the process returns to step 522, which results in lower power consumption for the refresh.

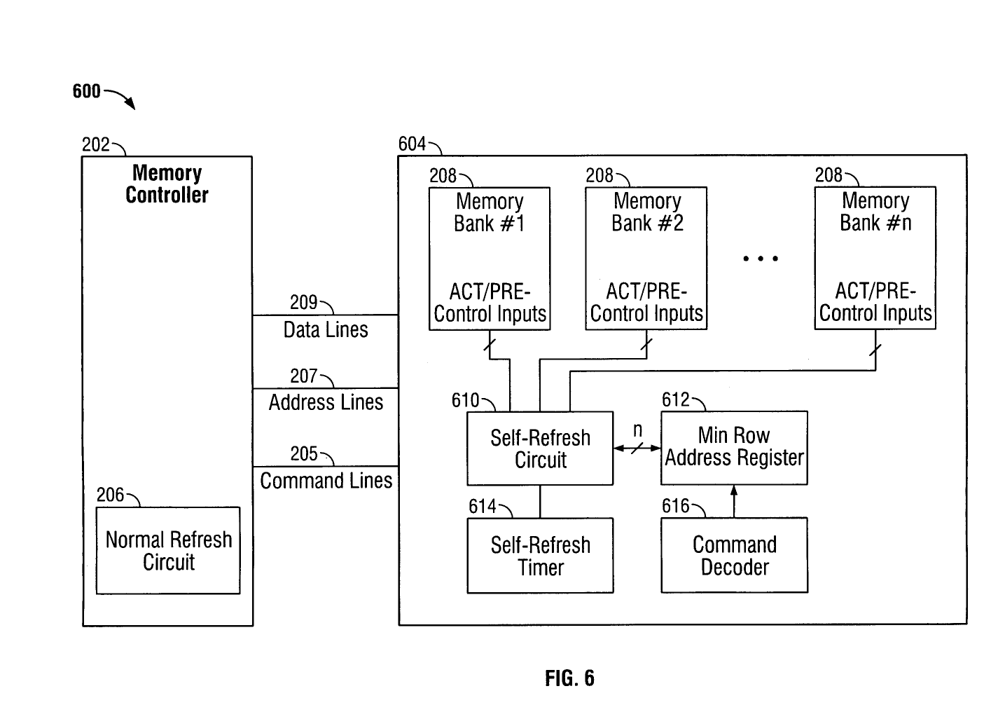

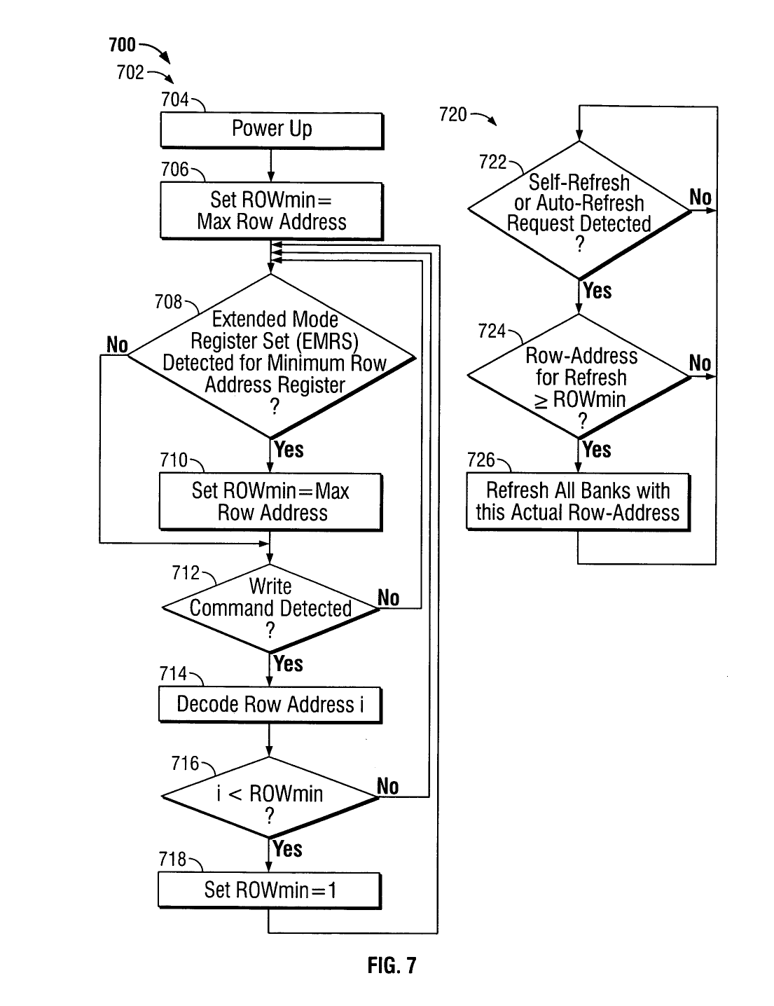

An alternative variation of the self-refresh memory device and corresponding self-refresh process of FIGS. 2-3 are shown in FIGS. 6-7, wherein components and processes similar to those shown in FIGS. 2-3 are identified with like numerals. As shown in FIG. 6, the memory device 604 includes a minimum row address register 612 that is in communication with both the command decoder 616 and the self-refresh circuit 610. It is a register which stores a single number that is as low as the lowest row-address of the memory banks 208.

The command decoder 616 monitors all write commands directed to the memory banks 208 and controls the contents of the minimum row address register 612. In the discussion to follow, the contents of the minimum row address register 612 will be denoted as ROWₘᵢₙ, a digital value which can cover the same range as the row-address space of the memory device 604.

The digital value of ROWₘᵢₙ of the minimum row address register 612 is initially set to a maximum row address value during the power-up sequence of the memory device 604. Afterwards, the value of ROWₘᵢₙ of the minimum row address register 612 is controlled by the command decoder 616 of the memory device 604. Whenever a write-command is issued to the memory device 604, the command decoder 616 decodes this write command and also decodes the row-address to which data are written. Whenever the decoded row-address is lower than the value of ROWₘᵢₙ presently stored in the minimum row address register 612, then the value of ROWₘᵢₙ is updated to have a value that corresponds to the presently decoded row-address. A command sequence—usually defined as an extended mode register set can be used to program/reset the value of ROWₘᵢₙ of the minimum row address register 612 to the maximum row address value or with an alternative implementation to any programmed value so as to declare the contents of the bank in question irrelevant.

The self-refresh circuit 610 monitors the contents of the minimum row address register 612 and starts the activate/precharge sequence only for those rows with an address that has a value that is greater than or equal to the stored value of ROWₘᵢₙ. For those rows with addresses that have a value that is less than the stored value of ROWₘᵢₙ, the self-refresh circuit 610 suppresses wordlines of those rows. Thus, the circuit 610 avoids unnecessary power consumption for refreshing row which are defined to not require to be refreshed by the minimum row address register 612. The circuit 610 can be altered in such a way that it either checks the minimum row address register 612 1) only in case of self-refresh mode or 2) both in self-refresh and auto-refresh mode.

As shown in FIG. 7, two parallel processes performed by decoder 616 are controlling the self-refresh—and with respective implementation also autorefresh—process 700. The two processes are performed by a global control circuit that includes the command decoder 616. The sub-process 702 controls the contents of the minimum row address register 612.

As shown in FIG. 7, the self-refresh process 700 involves at power up (step 704) resetting the value ROWₘᵢₙ stored in the minimum-row address register 612 to the maximum row address value per step 706. Next, the row-addresses of commands sent to the memory banks 208 are analyzed in the manner set forth below. In particular, detection of an extended mode register access for the minimum row address register 612 is performed per step 708. If extended mode register access is detected per step 708, then the value of ROWₘᵢₙ is reset to the value of the maximum row-address (step 710) or alternatively programmed to any other value (not illustrated) so as to declare the contents of the particular bank in question irrelevant. If an extended mode register access is not detected per step 708, then the value of ROWₘᵢₙ is not altered.

Irrespective of whether or not an extended mode register access is detected per step 708, the presence of a write command is determined per step 712. If a write command is detected, then the row-address i gets decoded by command decoder 216 per step 714. If no write command is decoded then the process returns to step 708, as shown in FIG. 7, where another command sent to the memory banks 208 is monitored.

If a write command is detected, a comparison between the decoded value i and the value of ROWₘᵢₙ is performed per step 716. In particular, if the decoded value i of the row-address is less than the value ROWₘᵢₙ, the value ROWₘᵢₙ is set to the decoded value i and stored in the minimum row address register per step 718. Then the process is repeated starting at step 708 where another command sent to the memory banks 208 is monitored.

Note that if the decoded value i is greater than or equal to the value ROWₘᵢₙ, per step 716, then the above-described process is repeated at step 708 where another command sent to the memory banks 208 is monitored.

The subprocess 720 shows the behavior during self-refresh and autorefresh requests. In particular, the command decoder 616 detects whenever a self-refresh or auto-refresh request for any row-address occurs per step 722. If no self-refresh or autorefresh is detected per step 722, then the process is then repeated and returns to step 722. If a self-refresh or autorefresh request is detected, then the value of the requested row-address for the refresh is compared with the value of ROWₘᵢₙ per step 724.

If the value of the requested row-address is higher or equal to the value ROWₘᵢₙ, then the rows of all banks 208 with this row-address are refreshed per step 726. The process is then repeated and returns to step 722.

Note that should the value of the requested row-address be determined in step 324 to be lower than the value ROWₘᵢₙ, then the refresh request is ignored and the process returns to step 322, which results in lower power consumption for the refresh.

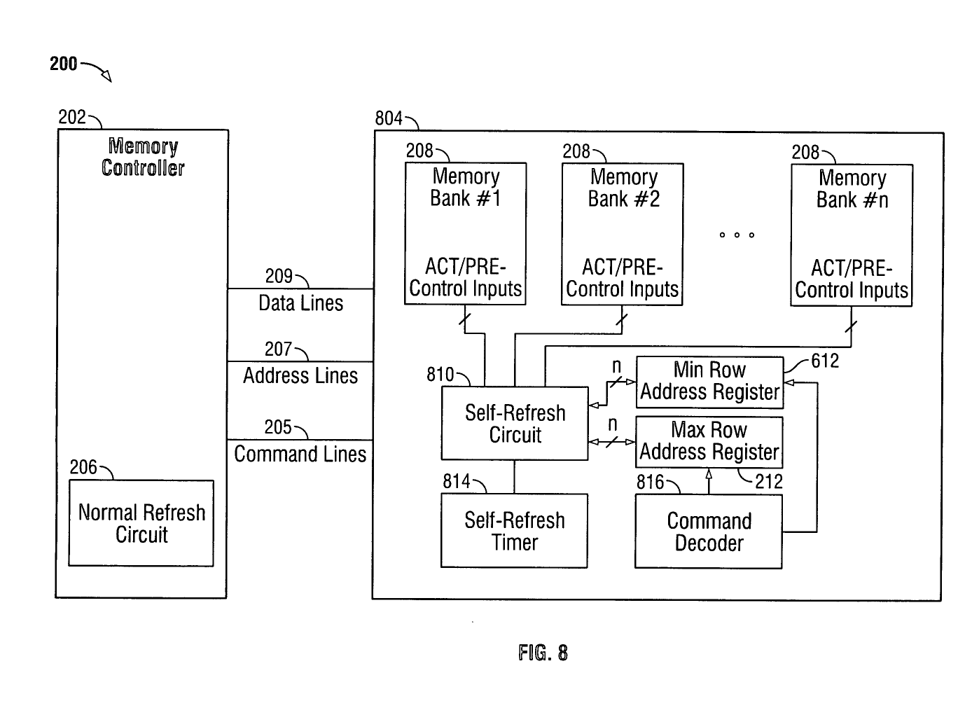

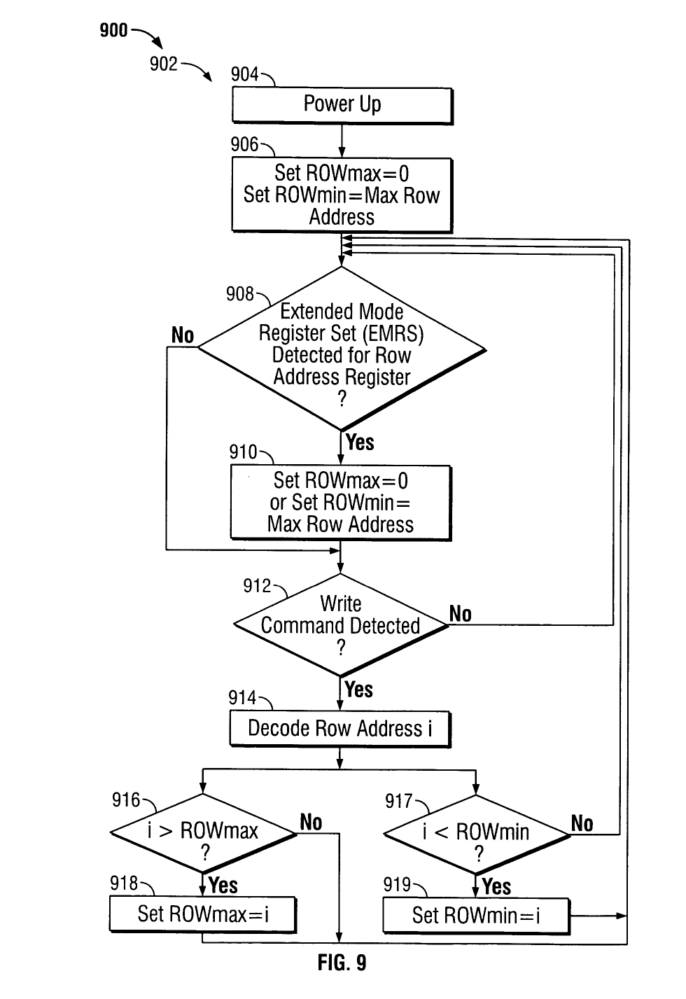

A second alternative variation of the self-refresh memory device and corresponding self-refresh process of FIGS. 2-3 is shown in FIGS. 8-9, wherein components and processes similar to those shown in FIGS. 2-3 and FIGS. 6-7 are identified with like numerals. As shown in FIG. 8, the memory device 804 includes both a maximum row address register 212 and a minimum row address register 612 that are in communication with both the command decoder 216 and the self-refresh circuit 210.

The command decoder monitors all write commands directed to the memory banks 208 and controls the contents of the maximum row address register 212 and the minimum row address register 612. The digital values of ROWₘₐₓ and ROWₘᵢₙ of the maximum row address register 212 and the minimum row address register 612 are initially set to zero and a maximum row address value, respectively, during the power-up sequence of the memory device 804. Afterwards, the values of ROWₘₐₓ and ROWₘᵢₙ are controlled by the command decoder 816 of the memory device 804. Whenever a write-command is issued to the memory device 804, the command decoder 816 decodes this write command and also decodes the row-address to which data are written. Whenever the decoded row-address is lower than the value of ROWₘᵢₙ, then the value of ROWₘᵢₙ is updated to have a value that corresponds to the presently decoded row-address. Similarly, whenever the decoded row-address is higher than the value of ROWₘₐₓ, then the value of ROWₘₐₓ is updated to have a value that corresponds to the presently decoded row-address.

A command sequence—usually defined as an extended mode register set can be used to program/reset the values of ROWₘᵢₙ and ROWₘₐₓ in a manner similar to that described with respect to the embodiments of FIGS. 2-3 and 6-7.

The self-refresh circuit 810 monitors the contents of the maximum row address register 212 and the minimum row address register 612 and starts the activate/precharge sequence only for those rows with an address that has a value that is less than or equal to the stored value of ROWₘᵢₙ and greater than or equal to the stored value of ROWₘₐₓ. For all other rows, the self-refresh circuit 810 suppresses wordlines of those rows. Thus, the circuit 810 avoids unnecessary power consumption for refreshing row which are defined to not require to be refreshed by the minimum row address register 612 and the maximum row address register 212. The circuit 810 can be altered in such a way that it either checks the maximum row address register 212 and the minimum row address register 612 1) only in case of self-refresh mode or 2) both in self-refresh and auto-refresh mode.

As shown in FIG. 9, two parallel processes are controlling the self-refresh—and with respective implementation also autorefresh—process 900. The two processes are performed by a global control circuit that includes the command decoder 816. The sub-process 902 controls the contents of both the maximum row address register 212 and the minimum row address register 612. The self-refresh process 900 involves at power up (step 904) resetting the values ROWₘₐₓ and ROWₘᵢₙ to zero and the maximum row address value, respectively, per step 906. Next, the row-addresses of commands sent to the memory banks 208 are analyzed in the manner set forth below. In particular, detection of an extended mode register access for the maximum row address register 212 and the minimum row address register 612 is performed per step 908. If extended mode register access is detected per step 908, then the value of ROWₘₐₓ is reset to zero or alternatively programmed to any other value (not illustrated) or ROWₘᵢₙ is reset to the value of the maximum row-address (step 910) or alternatively programmed to any other value (not illustrated) depending on whether the extended mode register access is detected to address the register 212 or register 612 so as to declare the contents of the particular bank in question irrelevant. If an extended mode register access is not detected per step 908, then the values of ROWₘₐₓ and ROWₘᵢₙ are not altered.

Irrespective of whether or not an extended mode register access is detected per step 908, the presence of a write command is determined per step 912. If a write command is detected, then the row-address i gets decoded by command decoder 816 per step 914. If no write command is decoded then the process returns to step 908, as shown in FIG. 9, where another command sent to the memory banks 208 is monitored.

If a write command is detected, a comparison between the decoded value i and the values of ROWₘₐₓ and ROWₘᵢₙ is performed in parallel per steps 916, 917. In particular, if the decoded value i of the row-address is greater than the value ROWₘₐₓ, the value ROWₘₐₓ is set to the decoded value i and stored in the maximum row address register per step 918. Similarly, if the decoded value i of the row-address is less than the value ROWₘᵢₙ, the value ROWₘᵢₙ is set to the decoded value i and stored in the minimum row address register per step 919. The process is repeated starting at step 908 where another command sent to the memory banks 208 is monitored.

Note that that while the addresses monitored at step 908 are not done sequentially, the addresses can be analyzed for each memory bank 208.

The subprocess 920 shows the behavior during self-refresh and autorefresh requests. In particular, the command decoder 816 detects whenever a self-refresh or auto-refresh request for any row-address occurs per step 922. If no self-refresh or autorefresh is detected per step 922, then the process is then repeated and returns to step 922. If a self-refresh or autorefresh request is detected, then the value of the requested row-address for the refresh is compared with the values of ROWₘₐₓ and ROWₘᵢₙ per step 924.

If the value of the requested row-address is lower or equal to the value ROWₘₐₓ and higher or equal to the value ROWₘᵢₙ, then the rows of all banks 208 with this row-address get refreshed per step 926. The process is then repeated and returns to step 922.

Note that should the value of the requested row-address be determined in step 924 to be either higher than ROWₘₐₓ or lower than the value ROWₘᵢₙ, then the refresh request gets ignored and the process returns to step 922, which results in lower power consumption for the refresh.

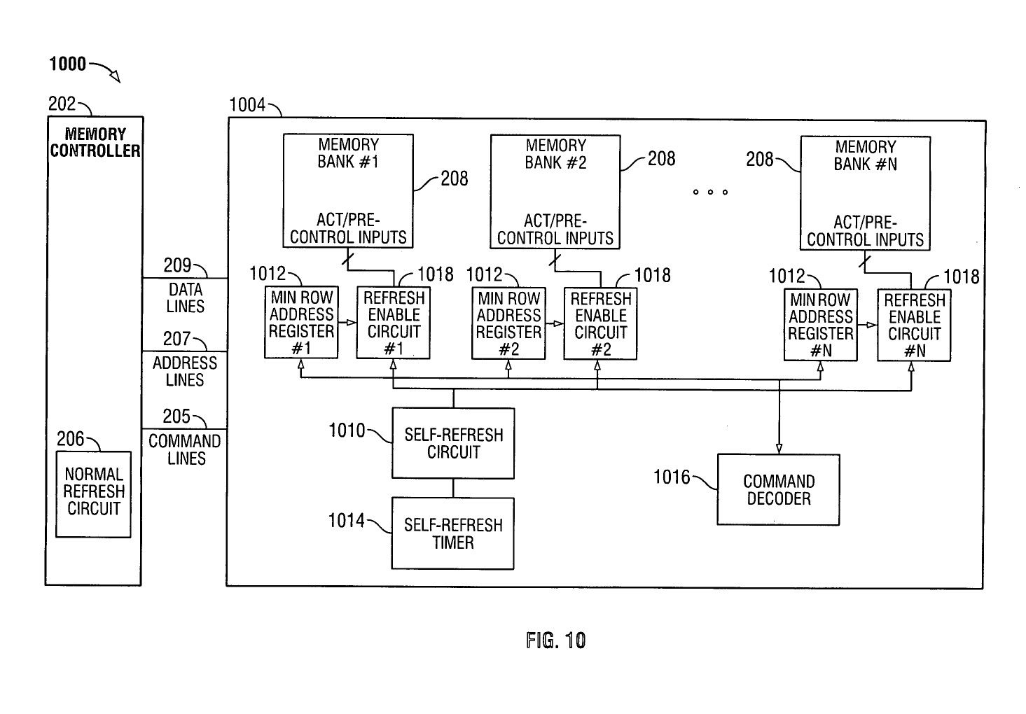

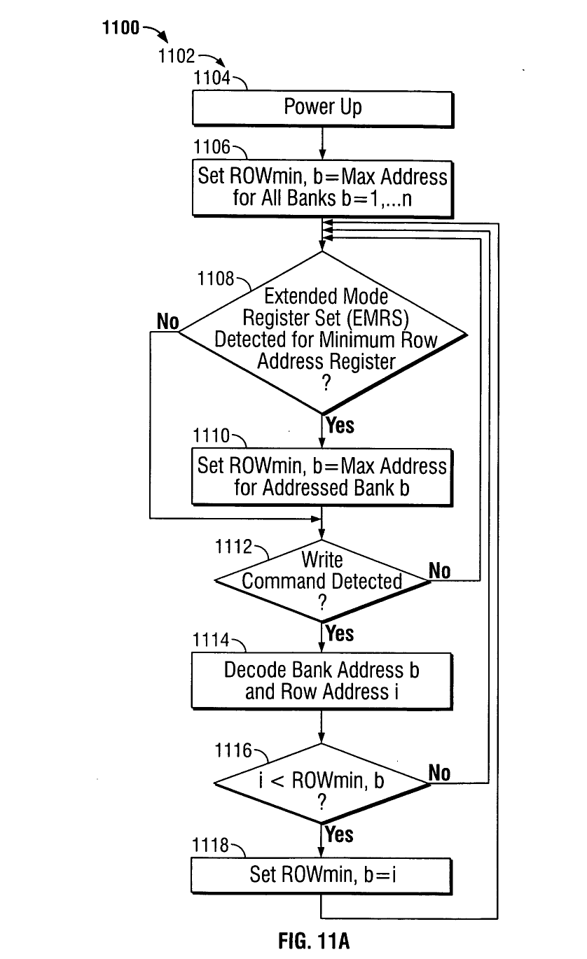

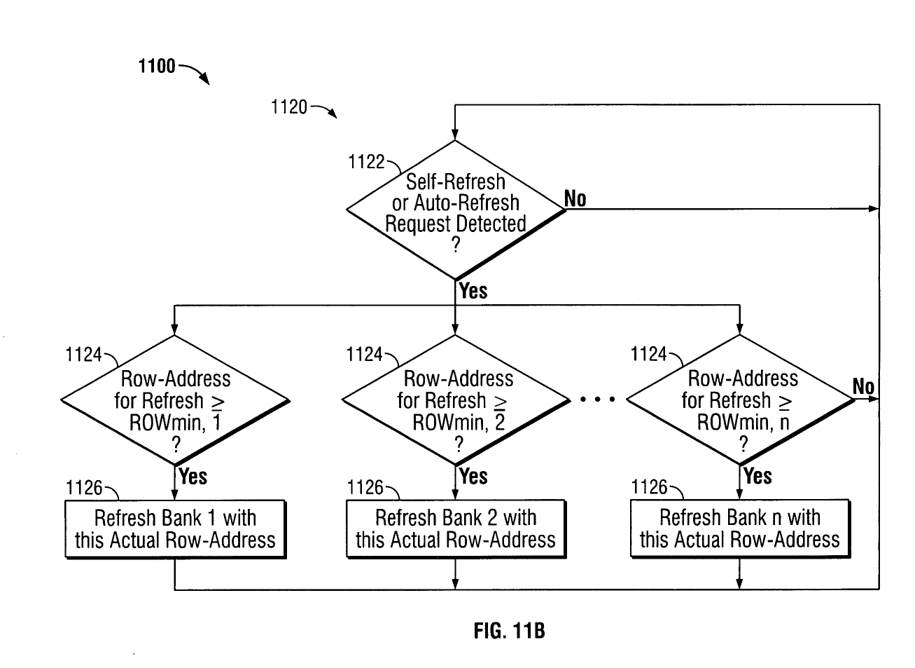

An alternative variation of the self-refresh memory device and corresponding self-refresh process of FIGS. 4-5 are shown in FIGS. 10-11, wherein components and processes similar to those shown in FIGS. 4-5 are identified with like numerals. As shown in FIG. 10, a memory system 1000 includes a memory controller 202 and a memory device 1004. The memory controller 202 has a normal refresh circuit 206 that performs a normal refresh operation in a manner similar to that described previously as explained previously with respect to FIGS. 4-5.

The memory controller 202 and the memory device 1004 are connected together by a bus 205 of command signals, a bus 207 of address signals, a bus 209 of data signals, clock signals (not illustrated) and datastrobe signals (not illustrated) in a manner similar to that described previously with respect to FIGS. 4-5.

The memory device 1004 has memory banks 208. Like the memory device 404 in FIG. 4, the memory device 1004 includes one address register per memory bank 208. Unlike memory device 404, the register is a minimum row address register 1012. The memory device 1004 also includes refresh enable circuits 1018, one for each memory bank 208.

The command decoder 1016 monitors all write commands directed to the memory banks 208 and controls the contents of the minimum row address registers 1012. The contents of the minimum row address register, connected to bank b will be denoted as ROW_{min,b}, a digital value which can cover the same range as the row-address space of the memory device.

The contents ROW_{min, b} (b=1, 2, . . . n) of all minimum row address are set to a maximum row address value at the power-up sequence of the memory device 1004. Afterwards, the contents of the minimum row address registers 1012 are controlled by the command decoder 1016 of the memory device 1004. Whenever a write-command is issued to the memory device 1004, the command decoder 1016 decodes this write command and also decodes the bank address b and the row-address to which data are written. The decoder 1016 then compares the value ROW_{min, b} of the minimum row address register corresponding to the bank b and the row-address of the decoded write command. If the row-address of the decoded write command is less than the value ROW_{min, b} of the minimum row address register 1012 of the addressed bank b, the value ROW_{min, b} of the minimum row address register 1012 for bank b is changed to value of the row-address of the decoded write command. A command sequence—usually defined as an extended mode register set—can be used to reset the minimum row address registers 1012 of all banks 208 to a maximum address value. Alternatively, an implementation is possible where each minimum row address register is reset individually with an extended mode register. Another implementation can allow setting the contents of all minimum row address registers to a programmable value. Another implementation allows setting the contents of each minimum row address register to a programmable value individually.

The self-refresh circuit 1010 shown in FIG. 10 sends refresh requests, including the row-address information, to refresh enable circuits 1018 for all banks 208. These refresh enable circuits 1018 monitor the contents of the minimum row address registers for a corresponding memory bank 208. Only if the row-address of the refresh request from the self-refresh circuit 1010 is greater or equal to the value of ROW_{min,b} of the minimum row-address register 1012 of a bank b, a refresh sequence is started for bank b. The circuit 1010 can be altered in such a way that it either does check the minimum row address register only in case of self-refresh mode or both in self-refresh and auto-refresh mode.

As shown in FIG. 11, the self-refresh process 1100 involves at power up (step 1104) resetting the value ROW_{min, b} stored in the minimum-row address registers 1012 for each memory bank b (b=1, 2, . . . n) to a maximum address value per step 1106. Next, the row-addresses of commands sent to the memory banks 208 are analyzed in the manner set forth below. In particular, detection of an extended mode register access for each of the minimum row address registers 1012 is performed per step 1108. If extended mode register access for a particular bank b is detected per step 1108, then the value of ROW_{min, b} of the minimum row address register 412 for addressed bank b is reset to the maximum address value (step 1110) or alternatively programmed to any other value (not illustrated) so as to declare the contents of the particular bank in question irrelevant. If an extended mode register access is not detected per step 1108, then the value of ROW_{min, b} is not altered.

Regardless of whether or not an extended mode register access is detected per step 1108, the presence of a write command is determined per step 1112. If a write command is detected, then the row-address i and addressed bank b gets decoded by command decoder 1016 per step 1114. If no write command is decoded then the process returns to step 1108, as shown in FIG. 11, where another command sent to the memory banks 208 is monitored.

If a write command is detected, the bank address b is decoded and a comparison between the decoded value of the row-address i and the value of ROW_{min, b} is performed per step 1116. In particular, if the decoded value i of the row-address is less than the value ROW_{min, b}, the value ROW_{min, b} is set to the decoded value i and stored in the minimum row address register 1012 corresponding to bank b per step 1118. Then the process is repeated starting at step 1108 where another command sent to the memory banks 208 is monitored.

Note that if the decoded value i is greater than or equal to the value ROW_{min, b}, per step 1116, then the above-described process is repeated at step 1108 where another command sent to the memory banks 208 is monitored.

The subprocess 1120 shows the behavior during self-refresh and autorefresh requests. In particular, the command decoder 1016 detects whenever a self-refresh or auto-refresh request for any row-address of a particular bank b occurs per step 1122. If no self-refresh or autorefresh is detected per step 1122, then the process is then repeated and returns to step 1122. If a self-refresh or autorefresh request is detected, then several parallel steps are started in parallel, one for each bank 208. In particular, the value of the requested row-address for the refresh is compared by the refresh enable circuits 1018 in parallel with each of the values of ROW_{min, b} of the banks 1, 2, . . . b per step 1124.

If the value of the requested row-address is greater than or equal to the value ROW_{min, b} of the minimum row address register 1012 for bank b, then bank b gets refreshed at this row-address of the refresh request per step 1126. The process is then repeated and returns to step 1122.

Note that should the value of the requested row-address be determined in step 1124 to be lower than the value ROW_{min, b}, then the refresh request for bank b of the requested row-address gets ignored and the process returns to step 1122, which results in lower power consumption for the refresh.

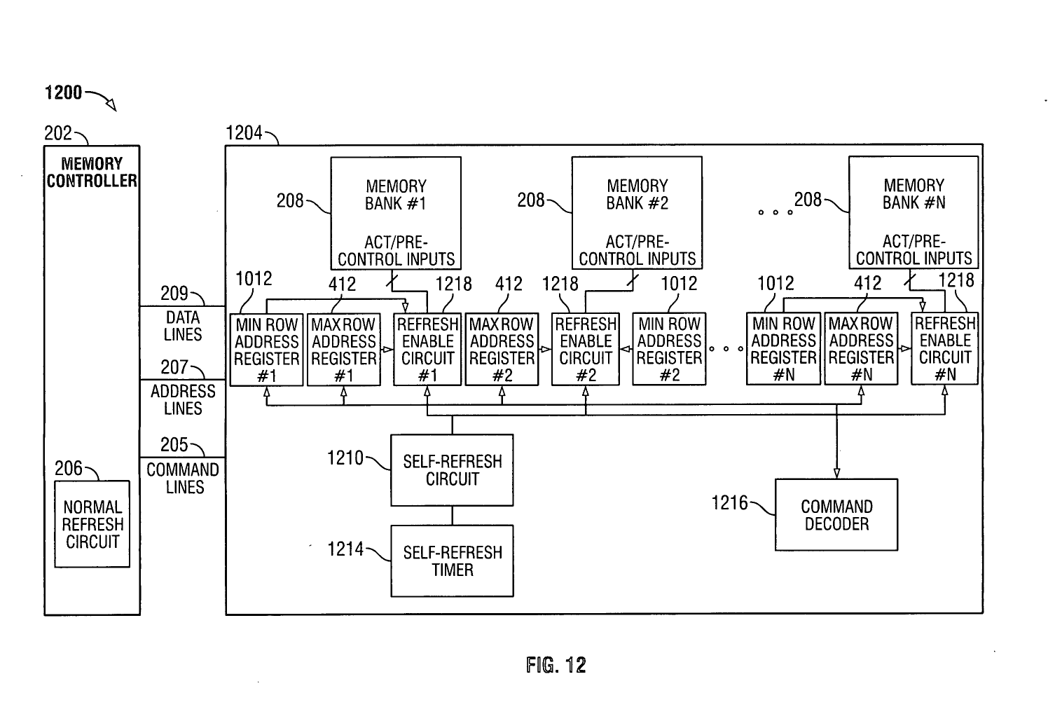

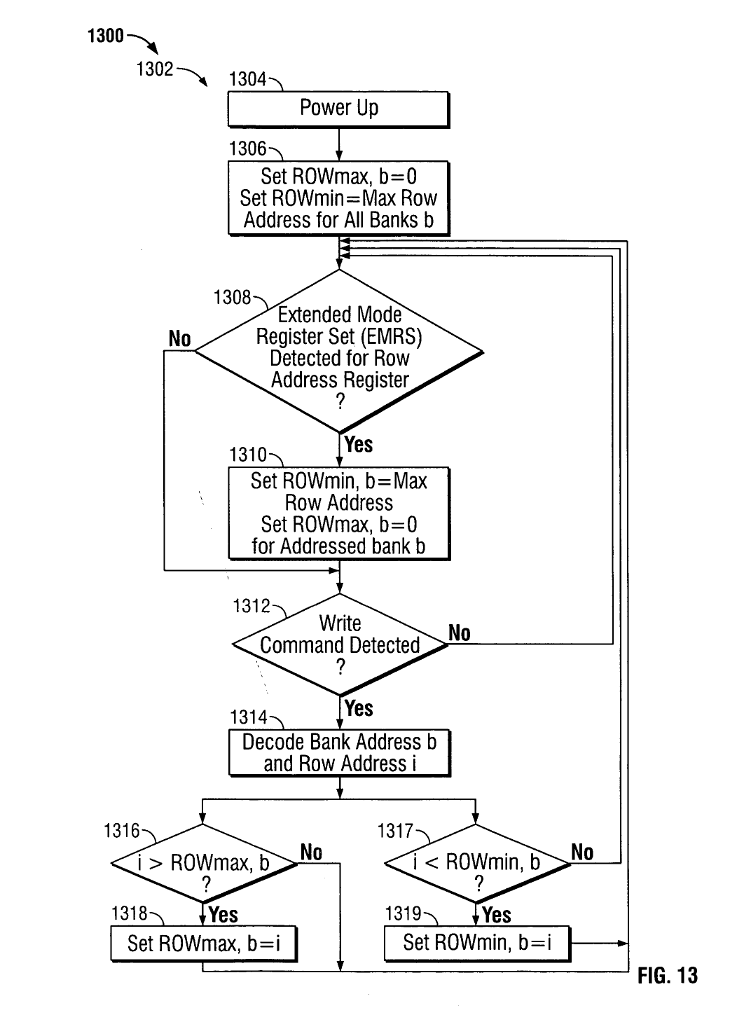

Another alternative variation of the self-refresh memory device and corresponding self-refresh process of FIGS. 4-5 is shown in FIGS. 12-13, wherein components and processes similar to those shown in FIGS. 4-5 are identified with like numerals. As shown in FIG. 12, a memory system 1200 includes a memory controller 202 and a memory device 1204. The memory controller 202 has a normal refresh circuit 206 that performs a normal refresh operation in a manner similar to that described previously as explained previously with respect to FIGS. 4-5.

The memory controller 202 and the memory device 1204 are connected together by a bus 205 of command signals, a bus 207 of address signals, a bus 209 of data signals, clock signals (not illustrated) and datastrobe signals (not illustrated) in a manner similar to that described previously with respect to FIGS. 4-5.

The memory device 1204 has memory banks 208. Like the memory device 404 in FIG. 4, the memory device 1004 includes one maximum address register 412 per memory bank 208. In addition, memory device 1004 includes one minimum address register 1012 per memory bank 208. The memory device 1204 also includes refresh enable circuits 1218, one for each memory bank 208.

The command decoder 1216 monitors all write commands directed to the memory banks 208 and controls the contents of the minimum row address registers 1012 and the maximum row address registers 412. The contents of the minimum and maximum row address registers, connected to bank b will be denoted as ROW_{min,b}, and ROW_{max, b}, respectively, digital values which can cover the same range as the row-address space of the memory device.

At power-up, the contents ROW_{min, b} (b=1, 2, . . . n) of all minimum row address registers are set to a maximum row address value. Similarly, the contents ROW_{max, b} (b=1, 2, . . . n) of all maximum row address registers are set to zero at the power-up sequence of the memory device 1204. Afterwards, the contents of the minimum row address registers 1012 and the maximum row address registers 412 are controlled by the command decoder 1216 of the memory device 1204. Whenever a write-command is issued to the memory device 1204, the command decoder 1216 decodes this write command and also decodes the bank address b and the row-address to which data are written. The decoder 1216 then compares the values ROW_{min,b} and ROW_{max,b} and the row-address of the decoded write command. If the row-address of the decoded write command is greater than the value ROW_{max,b} of the addressed bank b, the value ROW_{max,b} for bank b is changed to the value of the row-address of the decoded write command. If the row-address of the decoded write command is less than the value ROW_{min, b} of the addressed bank b, the value ROW_{min, b} for bank b is changed to value of the row-address of the decoded write command. A command sequence—usually defined as an extended mode register set—can be used to reset the minimum row address registers 1012 of all banks 208 to a maximum address value or alternatively programmed to any value. Similarly, the maximum row address registers 1012 of all banks 208 can be reset to zero or alternatively programmed to any value. Alternatively, an implementation is possible where each minimum row address register and each maximum row address register is reset individually or programmed individually to any value with an extended mode register set.

The self-refresh circuit 1210 shown in FIG. 12 sends refresh requests, including the row-address information, to refresh enable circuits 1218 for all banks 208. These refresh enable circuits 1218 monitor the contents of the minimum and maximum row address registers for a corresponding memory bank 208. Only if the row-address of the refresh request from the self-refresh circuit 1210 is greater than or equal to the value of ROW_{min,b} and less than or equal to the value of ROW_{max,b} for the registers 412, 1012 of a bank b, a refresh sequence is started for bank b. The circuit 1210 can be altered in such a way that it either does check the minimum and maximum row address registers only in case of self-refresh mode or both in self-refresh and auto-refresh mode.

As shown in FIG. 13, the self-refresh process 1300 involves at power up (step 1304) resetting the value ROW_{max,b} to zero and the value ROW_{min, b} to a maximum address value, for the registers 412, 1012, respectively, for each memory bank b (b=1, 2, . . . n) per step 1306. Next, the row-addresses of commands sent to the memory banks 208 are analyzed in the manner set forth below. In particular, detection of an extended mode register access for each of the minimum and maximum row address registers is performed per step 1308. If extended mode register access for a particular bank b is detected per step 1308, then the value of ROW_{max,b} is reset to zero or alternatively programmed to any other value (not illustrated) or ROW_{min, b} is reset or alternatively programmed to any other value (not illustrated) to the maximum address value (step 1310) depending on whether the extended mode register access is detected for register 412 or register 1012 so as to declare the content of the particular bank in question irrelevant. If an extended mode register access is not detected per step 1108, then the values of ROW_{max,b} and ROW_{min, b} are not altered.

Irrespective of whether or not an extended mode register access is detected per step 1308, the presence of a write command is determined per step 1312. If a write command is detected, then the row-address i and addressed bank b gets decoded by command decoder 1216 per step 1314. If no write command is decoded then the process returns to step 1308, as shown in FIG. 13, where another command sent to the memory banks 208 is monitored.

If a write command is detected, a comparison between the decoded value i and the values of ROW_{max,b} and ROW_{min, b} is performed per steps 1316 and 1317. In particular, if the decoded value i of the row-address is greater than the value ROW_{max,b}, the value ROW_{max,b} is set to the decoded value i and stored in the maximum row address register 412 corresponding to bank b per step 1318. If the decoded value i of the row-address is less than the value ROW_{min,b}, the value ROW_{min, b} is set to the decoded value i and stored in the minimum row address register 1012 corresponding to bank b per step 1319. Then the process is repeated starting at step 1308 where another command sent to the memory banks 208 is monitored.

The subprocess 1320 shows the behavior during self-refresh and autorefresh requests. In particular, the command decoder 1216 detects whenever a self-refresh or auto-refresh request for any row-address of a particular bank b occurs per step 1322. If no self-refresh or autorefresh is detected per step 1322, then the process is then repeated and returns to step 1322. If a self-refresh or autorefresh request is detected, then the value of the requested row-address of the requested bank b for the refresh is compared with the values of ROW_{max,b} and ROW_{min, b} of the banks 1, 2, . . . b per step 1324.

If the value of the requested row-address of the requested bank b is lower than or equal to the value ROW_{max,b} and greater than or equal to the value ROW_{min, b} for bank b, then bank b gets refreshed at this row-address of the refresh request per step 1326. The process is then repeated and returns to step 1322.

Note that should the value of the requested row-address be determined in step 1324 to be either greater than greater than the value ROW_{max,b} or less than the value ROW_{min,b}, then the refresh request for bank b of the requested row-address is ignored and the process returns to step 1322, which results in lower power consumption for the refresh.

Based on the above description of the processes shown in FIGS. 3, 5, 7, 9, 11 and 13, the design of the various components shown in FIGS. 2, 4, 6, 8, 10 and 12 based on existing DRAM products from vendors like Samsung, Micron, Elpida and Infineon is very straightforward for any DRAM designer or general logic designer.

The foregoing description is provided to illustrate the invention, and is not to be construed as a limitation. Numerous additions, substitutions and other changes can be made to the invention without departing from its scope as set forth in the appended claims.

1. A memory control system comprising:
a memory controller a memory device connected to said memory controller via a command bus, wherein command signals are directed from said memory controller to said memory device, said memory device comprising:
one or more memory banks;
a row address register;
a command decoder that is connected to said row address register and receives said command signals and controls the contents of said row address register; and
a refresh circuit connected to said one or more memory banks and said row address register, wherein said refresh circuit avoids unnecessary power consumption for refreshing said one or more memory banks.

2. The memory control system of claim 1, wherein said refresh circuit only refreshes a range of rows of said one or more memory banks based on a predetermined value stored in said row address register.

3. The memory control system of claim 1, wherein said row address register stores a predetermined value representative of the maximum row address of said one or more memory banks that receives a write command from said command signals.

4. The memory control system of claim 1, wherein said row address register stores a predetermined value representative of the minimum row address of said one or more memory banks that receives a write command from said command signals.

5. The memory control system of claim 2, wherein said row address register stores a predetermined value representative of the maximum row address of said one or more memory banks that receives a write command from said command signals; and said refresh circuit only refreshes rows of said one or more memory banks that have addresses less than or equal to said predetermined value.

6. The memory control system of claim 2, wherein said row address register stores a predetermined value representative of the minimum row address of said one or more memory banks that receives a write command from said command signals; and said refresh circuit only refreshes rows of said one or more memory banks that have addresses greater than or equal to said predetermined value.

7. The memory control system of claim 1, wherein said memory controller comprises a normal refresh circuit that sends an autorefresh signal to said memory device via said command bus.

8. The memory control system of claim 1, wherein said refresh circuit comprises:
a refresh address counter for incrementing a row address to be refreshed during a refresh cycle; and
a controller that controls access to a row address requested to be refreshed by a refresh request.

9. The memory control system of claim 1, wherein said refresh circuit performs refreshing as part of an autorefresh operation.

10. The memory control system of claim 1, wherein said refresh circuit performs refreshing as part of a self-refresh operation.

11. The memory control system of claim 1, wherein said memory controller comprises a normal refresh circuit.

12. A memory control system comprising:
a memory controller
a memory device connected to said memory controller via a command bus, wherein command signals are directed from said memory controller to said memory device, said memory device comprising:
one or more memory banks;
a first row address register;
a second row address register
a command decoder that is connected to said first row address register and said second row address register and receives said command signals and controls the contents of said first row address register and said second row address register; and
a refresh circuit connected to said one or more memory banks and said row address register, wherein said refresh circuit avoids unnecessary power consumption for refreshing said one or more memory banks.

13. The memory control system of claim 12, wherein said refresh circuit only refreshes a range of rows of said one or more memory banks based on a first predetermined value stored in said first row address register and a second predetermined value stored in said second row address register.

14. The memory control system of claim 13, wherein said first predetermined value is representative of the maximum row address of said one or more memory banks that receive a write command from said command signals.

15. The memory control system of claim 13, wherein said first predetermined value is representative of the minimum row address of said memory banks that receive a write command from said command signals.

16. The memory control system of claim 13, wherein said refresh circuit only refreshes rows of said one or more memory banks that have addresses less than or equal to said first predetermined value and greater than or equal to said second predetermined value.

17. The memory control system of claim 12, wherein said memory controller comprises a normal refresh circuit that sends an autorefresh signal to said memory device via said command bus.

18. The memory control system of claim 12, wherein said refresh circuit comprises:
a refresh address counter for incrementing a row address to be refreshed during a refresh cycle; and
a controller that controls access to a row address requested to be refreshed by a refresh request.

19. The memory control system of claim 12, wherein said refresh circuit performs refreshing as part of an autorefresh operation.

20. The memory control system of claim 12, wherein said refresh circuit performs refreshing as part of a self-refresh operation.

21. A memory control system comprising:
a memory controller
a memory device connected to said memory controller via a command bus, wherein command signals are directed from said memory controller to said memory device, said memory device comprising:
two or more memory banks;
one row address register for each of said two or more memory banks;
a command decoder that is connected to row address register and receives said command signals and controls the contents of said row address register; and
a refresh circuit connected to said two or more memory banks and said row address register, wherein said refresh circuit avoids unnecessary power consumption for refreshing said two or more memory banks.

22. The memory control system of claim 21, wherein said refresh circuit only refreshes a range of rows of said two or more memory banks based on predetermined values stored in said row address registers corresponding to said two or more memory banks.

23. The memory control system of claim 21, wherein each of said row address registers stores a predetermined value representative of the maximum row address of the corresponding memory bank of said two or more memory banks which was addressed during a write command from said command signals; and said refresh circuit only refreshes rows of said two or more memory banks that have addresses less than or equal to said predetermined values in the corresponding said address registers.

24. The memory control system of claim 21, wherein each of said row address registers stores a predetermined value representative of the minimum row address of the corresponding memory bank of said two or more memory banks which was addressed during a write command from said command signals; and said refresh circuit only refreshes rows of said two or more memory banks that have addresses greater than or equal to said predetermined values in the corresponding said address registers.

25. The memory control system of claim 21, further comprising a second row address register for each memory bank of said two or more memory banks that is connected to said command decoder and whose contents are controlled by said command decoder; and
wherein said row first address register stores a predetermined value representative of the maximum row address of the corresponding memory bank of said two or more memory banks which was addressed during a write command from said command signals; and said second row address register stores a second predetermined value representative of the minimum row address of the corresponding memory bank of said two or more memory banks which was addressed during a write command from said command signals; and said refresh circuit only refreshes rows of said memory banks that have addresses less than or equal to said predetermined value and greater than or equal to said second predetermined value in the two corresponding address registers.

26. The memory control system of claim 21, wherein said refresh circuit performs refreshing as part of an autorefresh operation.

27. The memory control system of claim 21, wherein said refresh circuit performs refreshing as part of a self-refresh operation.

28. A method of refreshing several memory banks that receive command signals from a memory controller, the method comprising:
monitoring command signals received by a memory device; and
refreshing said several memory banks based on said monitored command signals so as to avoid unnecessary power consumption for refreshing said several memory banks.

29. The method of claim 28, wherein said monitoring comprises determining whether or not a write command is received by said several memory banks of said memory device and indicating that said several memory banks contains data stored therein.

30. The method of claim 28, wherein said monitoring comprises determining a maximum row address for each of said several memory banks of said memory device that receives a write command; and
performing said refreshing based on said determined maximum row address.

31. The method of claim 28, wherein said monitoring comprises determining a minimum row address for each of said several memory banks of said memory device that receives a write command; and
performing said refreshing based on said determined minimum row address.

32. The method of claim 30, wherein said monitoring comprises determining a minimum row address of said memory that receives a write command; and
performing said refreshing based on said determined minimum row address.

33. The method of claim 28, wherein said refreshing is a self-refreshing operation.

34. The method of claim 28, wherein said refreshing is an auto-refreshing operation.
